(19) United States
(12) Patent Application Publication
(10) Pub. No.: US 2005/0167189 A1
(43) Pub. Date: Aug. 4, 2005

(54) Low cost acoustical structures manufactured from conductive loaded resin-based materials

(75) Inventor: Thomas Aisenbrey, Littleton, CO (US)

Correspondence Address: STEPHEN B. ACKERMAN, 28 DAVIS AVENUE, POUGHKEEPSIE, NY, 12603, US

(73) Assignee: Integral Technologies, Inc.

(21) Appl. No.: 11/096,822

(22) Filed: Apr. 1, 2005

Related U.S. Application Data
(63) Continuation-in-part of application No. 10/877,092, filed on Jun. 25, 2004.
Application No. 10/877,092 is a continuation of application No. 10/309,429, filed on Dec. 4, 2002, now Pat. No. 6,870,516.
Application No. 10/309,429 is a continuation-in-part of application No. 10/075,778, filed on Feb. 14, 2002, now Pat. No. 6,741,221.
(60) Provisional application No. 60/561,802, filed on Apr. 13, 2004.
(60) Provisional application No. 60/317,808, filed on Sep. 7, 2001.
(60) Provisional application No. 60/269,414, filed on Feb. 16, 2001.
(60) Provisional application No. 60/268,822, filed on Feb. 15, 2001.

(51) Int. Cl. H05K 5/00; A47B 81/06

(52) U.S. Cl. 181/199; 181/148

(57) ABSTRACT

Acoustical devices are formed of a conductive loaded resin-based material. The conductive loaded resin-based material comprises micron conductive powder(s), conductive fiber(s), or a combination of conductive powder and conductive fibers in a base resin host. The percentage by weight of the conductive powder(s), conductive fiber(s), or a combination thereof is between about 20% and 50% of the weight of the conductive loaded resin-based material. The micron conductive powders are formed from non-metals, such as carbon, graphite, that may also be metallic plated, or the like, or from metals such as stainless steel, nickel, copper, silver, that may also be metallic plated, or the like, or from a combination of non-metal, plated, or in combination with, metal powders. The micron conductor fibers preferably are of nickel plated carbon fiber, stainless steel fiber, copper fiber, silver fiber, aluminum fiber, or the like.

This Patent Application claims priority to the U.S. Provisional Patent Application No. 60/561,802 filed on Apr. 13, 2004, which is herein incorporated by reference in its entirety.

This Patent Application is a Continuation-in-Part of INT01-002CIPC, filed as U.S. Pat. application Ser. No. 10/877,092, filed on Jun. 25, 2004, which is a Continuation of INT01-002CIP, filed as U.S. patent application Ser. No. 10/309,429, filed on Dec. 4, 2002, also incorporated by reference in its entirety, which is a Continuation-in-Part application of docket number INT01-002, filed as U.S. Pat. application Ser. No. 10/075,778, filed on Feb. 14, 2002, now issued as U.S. Pat. No. 6,741,221, which claimed priority to U.S. Provisional Patent Applications Ser. No. 60/317,808, filed on Sep. 7, 2001, Ser. No. 60/269,414, filed on Feb. 16, 2001, and Ser. No. 60/268,822, filed on Feb. 15, 2001.

### BACKGROUND OF THE INVENTION

(1) Field of the Invention

This invention relates to acoustical devices and, more particularly, to acoustical devices molded of conductive loaded resin-based materials comprising micron conductive powders, micron conductive fibers, or a combination thereof, substantially homogenized within a base resin when molded. This manufacturing process yields a conductive part or material usable within the EMF or electronic spectrum(s).

(2) Description of the Prior Art

Acoustical devices are used for a variety of reasons in the art. In some applications, acoustical structures are used to reflect and focus sound wave energy. In other applications, acoustical structures are used to absorb or to diffuse sound energy. In yet other applications, acoustical structures are used to convert between electrical and sonic energy. In yet other applications, acoustical structures may be used to dissipate vibrational energy. Typically, acoustical structures are relatively high in density and, therefore, weight. An important object of the present invention is to create lower weight acoustical materials using conductive loaded resin-based material.

Several prior art inventions relate to acoustical articles and devices. U.S. Pat. No. 4,900,972 to Wersing et al teaches a method to form an electrode for a piezoelectric composite, such as would be used for an acoustical transducer. The piezoelectric composite comprises a ceramic substrate, an intrinsically conductive plastic film comprising polypyrrole, and a metal layer. U.S. Pat. No. 4,802,551 to Jacobsen teaches a load speaker unit where the cabinet walls of the load speaker are formed from a plastic material that is mixed with grains of comparably high specific gravity material. Plastics foams such as polyurethane, polystyrene, carbamide, or polyester are disclosed. U.S. Pat. No. 6,522,051 B1 to Nguyen et al teaches a sound probing device comprising an array of piezoelectric elements. Each piezoelectric element comprises a layer of piezoelectric material joined to a conductive film. This conductive film comprises an epoxy resin combined with a filler of metal particles (silver, copper, nickel) at 50% to 80% filler by volume. U.S. Pat. No. 4,284,168 to Gaus teaches an enclosure for a load speaker where the enclosure comprises an inner layer of plastic between outer layers of metal. U.S. Pat. No. Re. 38,351 E to Iseberg et al teaches high fidelity insert earphones and methods of manufacturing these earphones. The earphone housings comprise plastic.

### SUMMARY OF THE INVENTION

A principal object of the present invention is to provide an effective acoustical device.

A further object of the present invention is to provide a method to form an acoustical device.

A further object of the present invention is to provide an acoustical device molded of conductive loaded resin-based materials.

A further object of the present invention is to provide a vibration or sound absorbing spacer device molded of conductive loaded resin-based materials.

A further object of the present invention is to provide a vibration or sound absorbing panel device molded of conductive loaded resin-based materials.

A yet further object of the present invention is to provide an acoustical material with excellent sound reflection properties.

A yet further object of the present invention is to provide acoustical device molded of conductive loaded resin-based material where the device characteristics can be altered or the visual characteristics can be altered by forming a metal layer over the conductive loaded resin-based material.

A yet further object of the present invention is to provide a speaker enclosure device molded of the conductive loaded resin-based material.

A yet further object of the present invention is to provide an acoustical absorbing or diffusing device molded of the conductive loaded resin-based material.

A yet further object of the present invention is to provide a capacitive ultrasound transducer molded of conductive loaded resin-based material.

In accordance with the objects of this invention, a speaker device is achieved. The speaker device comprises a transducer capable of translating electrical energy into sound energy. An enclosure surrounds the transducer. The enclosure comprises a conductive loaded resin-based material comprising conductive materials in a base resin host.

Also in accordance with the objects of this invention, an acoustical device comprising an array of three-dimensional shapes each comprising conductive loaded resin-based material comprising conductive materials in a base resin host. The weight of the conductive materials is between 20% and 50% of the total weight of the conductive loaded resin-based material.

Also in accordance with the objects of this invention, a capacitive acoustical transducer device is achieved. The device comprises a first conductive electrode comprising conductive loaded resin-based material comprising conductive materials in a base resin host. A second conductive electrode comprises the conductive loaded resin-based material comprising the conductive materials in the base resin host. A membrane layer is on the first conductive electrode. An insulating layer is on the second conductive electrode.

Also in accordance with the objects of this invention, a method to form a speaker device is achieved. The method comprises providing a transducer capable of translating electrical energy into sound energy. A conductive loaded, resin-based material comprising conductive materials in a resin-based host is provided. The conductive loaded, resin-based material is formed into an enclosure surrounding the transducer.

Also in accordance with the objects of this invention, a method to form an acoustical device is achieved. The method comprises providing a conductive loaded, resin-based material comprising conductive materials in a resin-based host. The weight of the conductive materials is between 20% and 50% of the total weight of the conductive loaded resin-based material. The conductive loaded, resin-based material is formed into an array of three-dimensional shapes.

Also in accordance with the objects of this invention, a method to form a capacitive acoustical transducer device is achieved. The method comprises providing a conductive loaded, resin-based material comprising micron conductive fiber in a resin-based host. The conductive loaded, resin-based material is formed into a first conductive electrode. The conductive loaded, resin-based material is formed into a second conductive electrode. The first conductive electrode is fixed to a membrane layer. The second conductive electrode is fixed to an insulating layer.

### BRIEF DESCRIPTION OF THE DRAWINGS

In the accompanying drawings forming a material part of this description, there is shown:

FIG. 1 illustrates a first preferred embodiment of the present invention showing an acoustic device formed of the conductive loaded resin-based material according to the present invention.

FIG. 2 illustrates a first preferred embodiment of a conductive loaded resin-based material wherein the conductive materials comprise a powder.

FIG. 3 illustrates a second preferred embodiment of a conductive loaded resin-based material wherein the conductive materials comprise micron conductive fibers.

FIG. 4 illustrates a third preferred embodiment of a conductive loaded resin-based material wherein the conductive materials comprise both conductive powder and micron conductive fibers.

FIGS. 5a and 5b illustrate a fourth preferred embodiment wherein conductive fabric-like materials are formed from the conductive loaded resin-based material.

FIGS. 6a and 6b illustrate, in simplified schematic form, an injection molding apparatus and an extrusion molding apparatus that may be used to mold acoustical articles of a conductive loaded resin-based material.

FIGS. 7a and 7b illustrate a second preferred embodiment of the present invention showing a loudspeaker enclosure comprising the conductive loaded resin-based material of the present invention.

FIG. 8 illustrates a third preferred embodiment of the present invention showing a sound diffusing or sound absorbing structure comprising the conductive loaded resin-based material of the present invention.

FIG. 9 illustrates fourth preferred embodiment of the present invention showing a capacitive ultrasound transducer comprising the conductive loaded resin-based material of the present invention.

FIG. 10 illustrates a fifth preferred embodiment of the present invention showing sound or vibration absorbing spacers comprising the conductive loaded resin-based material of the present invention.

FIG. 11 illustrates a sixth preferred embodiment of the present invention showing sound or vibration absorbing panels comprising the conductive loaded resin-based material of the present invention.

### DESCRIPTION OF THE PREFERRED EMBODIMENTS

This invention relates to acoustical devices molded of conductive loaded resin-based materials comprising micron conductive powders, micron conductive fibers, or a combination thereof, substantially homogenized within a base resin when molded.

The conductive loaded resin-based materials of the invention are base resins loaded with conductive materials, which then makes any base resin a conductor rather than an insulator. The resins provide the structural integrity to the molded part. The micron conductive fibers, micron conductive powders, or a combination thereof, are substantially homogenized within the resin during the molding process, providing the electrical continuity.

The conductive loaded resin-based materials can be molded, extruded or the like to provide almost any desired shape or size. The molded conductive loaded resin-based materials can also be cut, stamped, or vacuumed formed from an injection molded or extruded sheet or bar stock, over-molded, laminated, milled or the like to provide the desired shape and size. The thermal or electrical conductivity characteristics of acoustical devices fabricated using conductive loaded resin-based materials depend on the composition of the conductive loaded resin-based materials, of which the loading or doping parameters can be adjusted, to aid in achieving the desired structural, electrical or other physical characteristics of the material. The selected materials used to fabricate the acoustical devices are substantially homogenized together using molding techniques and or methods such as injection molding, over-molding, insert molding, thermo-set, protrusion, extrusion or the like. Characteristics related to 2D, 3D, 4D, and 5D designs, molding and electrical characteristics, include the physical and electrical advantages that can be achieved during the molding process of the actual parts and the polymer physics associated within the conductive networks within the molded part(s) or formed material(s).

In the conductive loaded resin-based material, electrons travel from point to point when under stress, following the path of least resistance. Most resin-based materials are insulators and represent a high resistance to electron passage. The doping of the conductive loading into the resin-based material alters the inherent resistance of the polymers. At a threshold concentration of conductive loading, the resistance through the combined mass is lowered enough to allow electron movement. Speed of electron movement depends on conductive loading concentration, that is, the separation between the conductive loading particles. Increasing conductive loading content reduces interparticle separation distance, and, at a critical distance known as the percolation point, resistance decreases dramatically and electrons move rapidly.

Resistivity is a material property that depends on the atomic bonding and on the microstructure of the material. The atomic microstructure material properties within the conductive loaded resin-based material are altered when molded into a structure. A substantially homogenized conductive microstructure of delocalized valance electrons is created. This microstructure provides sufficient charge carriers within the molded matrix structure. As a result, a low density, low resistivity, lightweight, durable, resin based polymer microstructure material is achieved. This material exhibits conductivity comparable to that of highly conductive metals such as silver, copper or aluminum, while maintaining the superior structural characteristics found in many plastics and rubbers or other structural resin based materials.

The use of conductive loaded resin-based materials in the fabrication of acoustical devices significantly lowers the cost of materials and the design and manufacturing processes used to hold ease of close tolerances, by forming these materials into desired shapes and sizes. The acoustical devices can be manufactured into infinite shapes and sizes using conventional forming methods such as injection molding, over-molding, or extrusion or the like. The conductive loaded resin-based materials, when molded, typically but not exclusively produce a desirable usable range of resistivity from between about 5 and 25 ohms per square, but other resistivities can be achieved by varying the doping parameters and/or resin selection(s).

The conductive loaded resin-based materials comprise micron conductive powders, micron conductive fibers, or any combination thereof, which are substantially homogenized together within the base resin, during the molding process, yielding an easy to produce low cost, electrically conductive, close tolerance manufactured part or circuit. The resulting molded article comprises a three dimensional, continuous network of conductive loading and polymer matrix. The micron conductive powders can be of carbons, graphites, amines or the like, and/or of metal powders such as nickel, copper, silver, aluminum, or plated or the like. The use of carbons or other forms of powders such as graphite(s) etc. can create additional low level electron exchange and, when used in combination with micron conductive fibers, creates a micron filler element within the micron conductive network of fiber(s) producing further electrical conductivity as well as acting as a lubricant for the molding equipment. The micron conductive fibers can be nickel plated carbon fiber, stainless steel fiber, copper fiber, silver fiber, aluminum fiber, or the like, or combinations thereof. Superconductor metals, such as titanium, nickel, niobium, and zirconium, and alloys of titanium, nickel, niobium, and zirconium may also be used as micron conductive fibers in the present invention. The structural material is a material such as any polymer resin. Structural material can be, here given as examples and not as an exhaustive list, polymer resins produced by GE PLASTICS, Pittsfield, Mass., a range of other plastics produced by GE PLASTICS, Pittsfield, Mass., a range of other plastics produced by other manufacturers, silicones produced by GE SILICONES, Waterford, N.Y., or other flexible resin-based rubber compounds produced by other manufacturers.

The resin-based structural material loaded with micron conductive powders, micron conductive fibers, or in combination thereof can be molded, using conventional molding methods such as injection molding or over-molding, or extrusion to create desired shapes and sizes. The molded conductive loaded resin-based materials can also be stamped, cut or milled as desired to form create the desired shape form factor(s) of the acoustical devices. The doping composition and directionality associated with the micron conductors within the loaded base resins can affect the electrical and structural characteristics of the acoustical devices and can be precisely controlled by mold designs, gating and or protrusion design(s) and or during the molding process itself. In addition, the resin base can be selected to obtain the desired thermal characteristics such as very high melting point or specific thermal conductivity.

A resin-based sandwich laminate could also be fabricated with random or continuous webbed micron stainless steel fibers or other conductive fibers, forming a cloth like material. The webbed conductive fiber can be laminated or the like to materials such as Teflon, Polyesters, or any resin-based flexible or solid material(s), which when discretely designed in fiber content(s), orientation(s) and shape(s), will produce a very highly conductive flexible cloth-like material. Such a cloth-like material could also be used in forming acoustical devices that could be embedded in a person's clothing as well as other resin materials such as rubber(s) or plastic(s). When using conductive fibers as a webbed conductor as part of a laminate or cloth-like material, the fibers may have diameters of between about 3 and 12 microns, typically between about 8 and 12 microns or in the range of about 10 microns, with length(s) that can be seamless or overlapping.

The conductive loaded resin-based material of the present invention can be made resistant to corrosion and/or metal electrolysis by selecting micron conductive fiber and/or micron conductive powder and base resin that are resistant to corrosion and/or metal electrolysis. For example, if a corrosion/electrolysis resistant base resin is combined with stainless steel fiber and carbon fiber/powder, then a corrosion and/or metal electrolysis resistant conductive loaded resin-based material is achieved. Another additional and important feature of the present invention is that the conductive loaded resin-based material of the present invention may be made flame retardant. Selection of a flame-retardant (FR) base resin material allows the resulting product to exhibit flame retardant capability. This is especially important in acoustical device applications as described herein.

The substantially homogeneous mixing of micron conductive fiber and/or micron conductive powder and base resin described in the present invention may also be described as doping. That is, the substantially homogeneous mixing converts the typically non-conductive base resin material into a conductive material. This process is analogous to the doping process whereby a semiconductor material, such as silicon, can be converted into a conductive material through the introduction of donor/acceptor ions as is well known in the art of semiconductor devices. Therefore, the present invention uses the term doping to mean converting a typically non-conductive base resin material into a conductive material through the substantially homogeneous mixing of micron conductive fiber and/or micron conductive powder into a base resin.

As an additional and important feature of the present invention, the molded conductor loaded resin-based material exhibits excellent thermal dissipation characteristics. Therefore, acoustical devices manufactured from the molded conductor loaded resin-based material can provide added thermal dissipation capabilities to the application. For example, heat can be dissipated from electrical devices physically and/or electrically connected to acoustical devices of the present invention.

As a significant advantage of the present invention, acoustical devices constructed of the conductive loaded resin-based material can be easily interfaced to an electrical circuit or grounded. In one embodiment, a wire can be attached to a conductive loaded resin-based acoustical device via a screw that is fastened to the acoustical device. For example, a simple sheet-metal type, self tapping screw, when fastened to the material, can achieve excellent electrical connectivity via the conductive matrix of the conductive loaded resin-based material. To facilitate this approach a boss may be molded into the conductive loaded resin-based material to accommodate such a screw. Alternatively, if a solderable screw material, such as copper, is used, then a wire can be soldered to the screw that is embedded into the conductive loaded resin-based material. In another embodiment, the conductive loaded resin-based material is partly or completely plated with a metal layer. The metal layer forms excellent electrical conductivity with the conductive matrix. A connection of this metal layer to another circuit or to ground is then made. For example, if the metal layer is solderable, then a soldered connection may be made between the acoustical device and a grounding wire.

A typical metal deposition process for forming a metal layer onto the conductive loaded resin-based material is vacuum metallization. Vacuum metallization is the process where a metal layer, such as aluminum, is deposited on the conductive loaded resin-based material inside a vacuum chamber. In a metallic painting process, metal particles, such as silver, copper, or nickel, or the like, are dispersed in an acrylic, vinyl, epoxy, or urethane binder. Most resin-based materials accept and hold paint well, and automatic spraying systems apply coating with consistency. In addition, the excellent conductivity of the conductive loaded resin-based material of the present invention facilitates the use of extremely efficient, electrostatic painting techniques.

The conductive loaded resin-based material can be contacted in any of several ways. In one embodiment, a pin is embedded into the conductive loaded resin-based material by insert molding, ultrasonic welding, pressing, or other means. A connection with a metal wire can easily be made to this pin and results in excellent contact to the conductive loaded resin-based material. In another embodiment, a hole is formed in to the conductive loaded resin-based material either during the molding process or by a subsequent process step such as drilling, punching, or the like. A pin is then placed into the hole and is then ultrasonically welded to form a permanent mechanical and electrical contact. In yet another embodiment, a pin or a wire is soldered to the conductive loaded resin-based material. In this case, a hole is formed in the conductive loaded resin-based material either during the molding operation or by drilling, stamping, punching, or the like. A solderable layer is then formed in the hole. The solderable layer is preferably formed by metal plating. A conductor is placed into the hole and then mechanically and electrically bonded by point, wave, or reflow soldering.

Another method to provide connectivity to the conductive loaded resin-based material is through the application of a solderable ink film to the surface. One exemplary solderable ink is a combination of copper and solder particles in an epoxy resin binder. The resulting mixture is an active, screen-printable and dispensable material. During curing, the solder reflows to coat and to connect the copper particles and to thereby form a cured surface that is directly solderable without the need for additional plating or other processing steps. Any solderable material may then be mechanically and/or electrically attached, via soldering, to the conductive loaded resin-based material at the location of the applied solderable ink. Many other types of solderable inks can be used to provide this solderable surface onto the conductive loaded resin-based material of the present invention. Another exemplary embodiment of a solderable ink is a mixture of one or more metal powder systems with a reactive organic medium. This type of ink material is converted to solderable pure metal during a low temperature cure without any organic binders or alloying elements.

A ferromagnetic conductive loaded resin-based material may be formed of the present invention to create a magnetic or magnetizable form of the material. Ferromagnetic micron conductive fibers and/or ferromagnetic conductive powders are mixed with the base resin. Ferrite materials and/or rare earth magnetic materials are added as a conductive loading to the base resin. With the substantially homogeneous mixing of the ferromagnetic micron conductive fibers and/or micron conductive powders, the ferromagnetic conductive loaded resin-based material is able to produce an excellent low cost, low weight magnetize-able item. The magnets and magnetic devices of the present invention can be magnetized during or after the molding process. The magnetic strength of the magnets and magnetic devices can be varied by adjusting the amount of ferromagnetic micron conductive fibers and/or ferromagnetic micron conductive powders that are incorporated with the base resin. By increasing the amount of the ferromagnetic doping, the strength of the magnet or magnetic devices is increased. The substantially homogenous mixing of the conductive fiber network allows for a substantial amount of fiber to be added to the base resin without causing the structural integrity of the item to decline. The ferromagnetic conductive loaded resin-based magnets display the excellent physical properties of the base resin, including flexibility, moldability, strength, and resistance to environmental corrosion, along with excellent magnetic ability. In addition, the unique ferromagnetic conductive loaded resin-based material facilitates formation of items that exhibit excellent thermal and electrical conductivity as well as magnetism.

A high aspect ratio magnet is easily achieved through the use of ferromagnetic conductive micron fiber or through the combination of ferromagnetic micron powder with conductive micron fiber. The use of micron conductive fiber allows for molding articles with a high aspect ratio of conductive fiber to cross sectional area. If a ferromagnetic micron fiber is used, then this high aspect ratio translates into a high quality magnetic article. Alternatively, if a ferromagnetic micron powder is combined with micron conductive fiber, then the magnetic effect of the powder is effectively spread throughout the molded article via the network of conductive fiber such that an effective high aspect ratio molded magnetic article is achieved. The ferromagnetic conductive loaded resin-based material may be magnetized, after molding, by exposing the molded article to a strong magnetic field. Alternatively, a strong magnetic field may be used to magnetize the ferromagnetic conductive loaded resin-based material during the molding process.

Exemplary ferromagnetic conductive fiber materials include ferrite, or ceramic, materials as nickel zinc, manganese zinc, and combinations of iron, boron, and strontium, and the like. In addition, rare earth elements, such as neodymium and samarium, typified by neodymium-iron-boron, samarium-cobalt, and the like, are useful ferromagnetic conductive fiber materials. Exemplary non-ferromagnetic conductor fibers include stainless steel, nickel, copper, silver, aluminum, or other suitable metals or conductive fibers, alloys, plated materials, or combinations thereof. Superconductor metals, such as titanium, nickel, niobium, and zirconium, and alloys of titanium, nickel, niobium, and zirconium may also be used as micron conductive fibers in the present invention. Exemplary ferromagnetic micron powder leached onto the conductive fibers include ferrite, or ceramic, materials as nickel zinc, manganese zinc, and combinations of iron, boron, and strontium, and the like. In addition, rare earth elements, such as neodymium and samarium, typified by neodymium-iron-boron, samarium-cobalt, and the like, are useful ferromagnetic conductive powder materials.

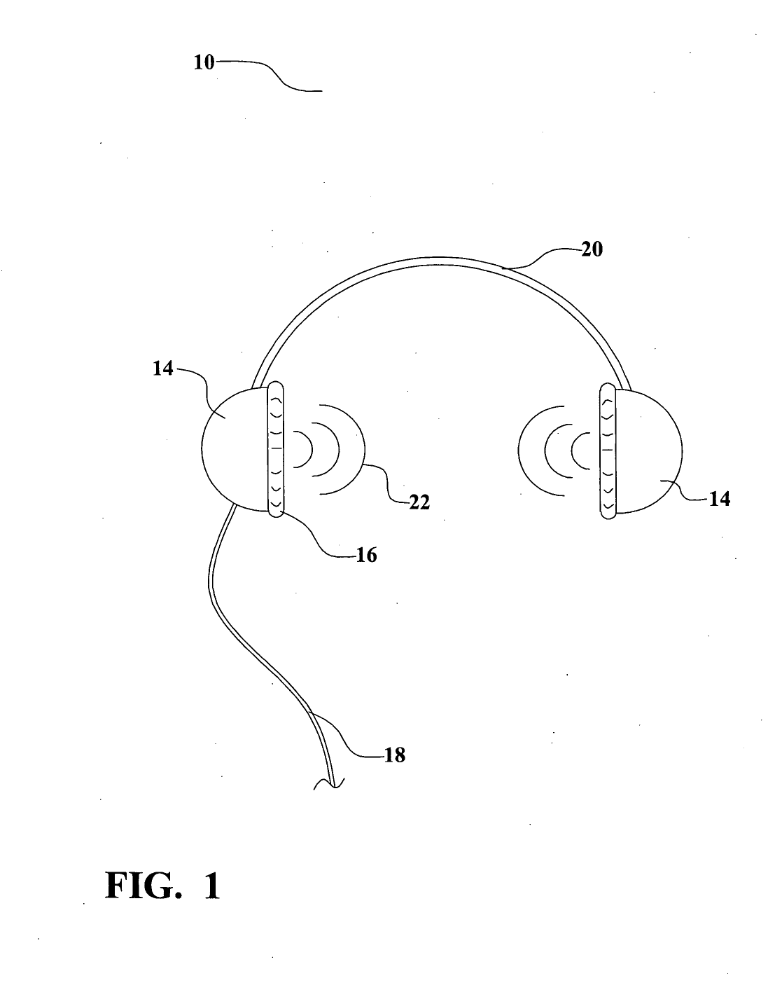

Referring now to FIG. 1, a first preferred embodiment of the present invention is illustrated. An acoustical device 10 comprising the conductive loaded resin-based material of the present invention is shown. Several important features of the present invention are shown and discussed below. The first preferred embodiment acoustical article is a portable audio headset 10. The audio headset 10 comprises an audio speaker enclosures 14 coupled to a headband 20 such that each speaker enclosure 14 can be suspended near the wearer's right and left ears. An electrical signal is transmitted to the headset through an electrical wire 18. In this example, the wire 18 is directly connected to the left side speaker and is routed to the right side speaker through the headband 20. Foam inserts 16 may also be included in the headset assembly 10 to improve comfort.

As an important feature of the present invention, the speaker enclosures 14 are molded from a conductive loaded resin-based material as described herein. The conductive loaded resin-based material provides several advantages when applied to speaker enclosures 14. First, the conductive loading material greatly increases the density of the base resin to thereby create an enclosure 14 with voids and baffle structures that diffuse and/or dissipate the sound generated by the speaker that impinges upon the enclosure 14 itself. Thus a maximum amount of sound energy 22 is focused toward the wearer's ear with the least amount of sound coloration. Second, this high density material tends to diffuse and/or dissipate any external sounds to thereby isolate the wearer from external noises. Therefore, the headphones effectively suppress or reduce external noise intrusion while improving internal sound reproduction. Third, the conductive loaded resin-based material retains the resin-based characteristics such as ease of manufacture by molding processing. Finally, the resin-based characteristics of non-corrosion and non-reactivity are retained. In one embodiment, the enclosure 14 is easily formed by injection molding. In another embodiment, the enclosure 14 is formed by blow molding to form a hollow enclosure.

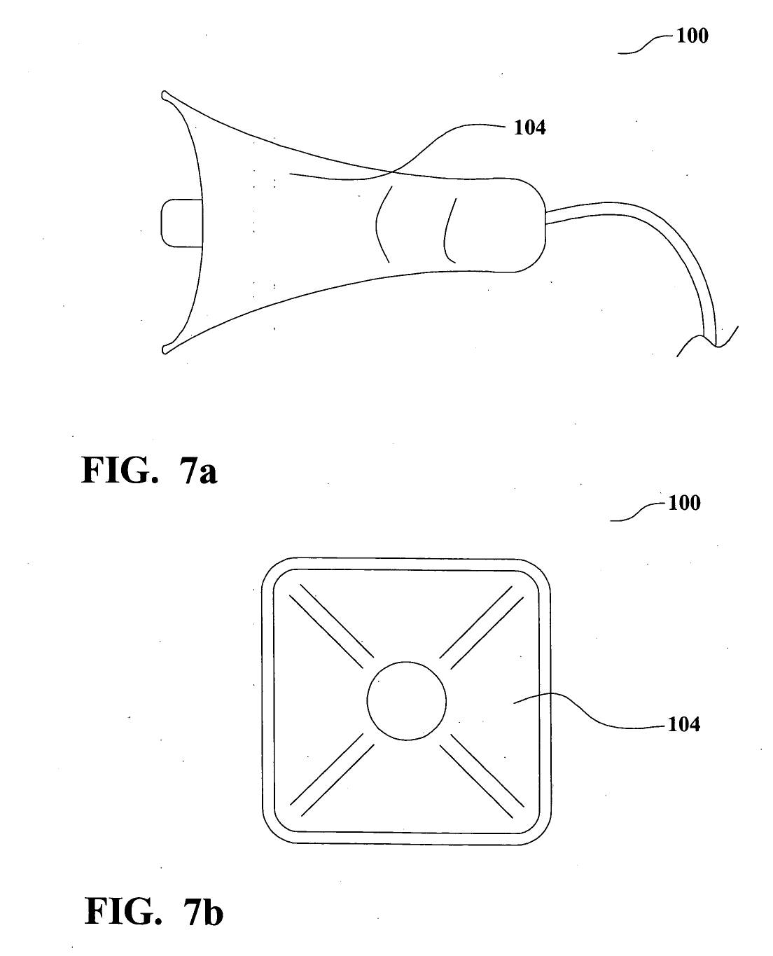

Referring now to FIGS. 7a and 7b, a second preferred embodiment of the present invention is illustrated. A loudspeaker 100 is shown. More particularly, the acoustical enclosure 104 of the loudspeaker 100 is molded from the conductive loaded resin-based material. The acoustical enclosure 104 in this application includes the surrounding body or casing of the loudspeaker 100 as well as the interior flange of the horn. The structure of the acoustical enclosure 104 diffuses or dissipates sound impinging upon the acoustical enclosure 104 to minimize the amount of sound coloration and allow reproducing the amplified sound that is being applied to the speaker. In one embodiment, the enclosure 104 is easily formed by injection molding. In another embodiment, the enclosure 104 is formed by blow molding to form a hollow enclosure.

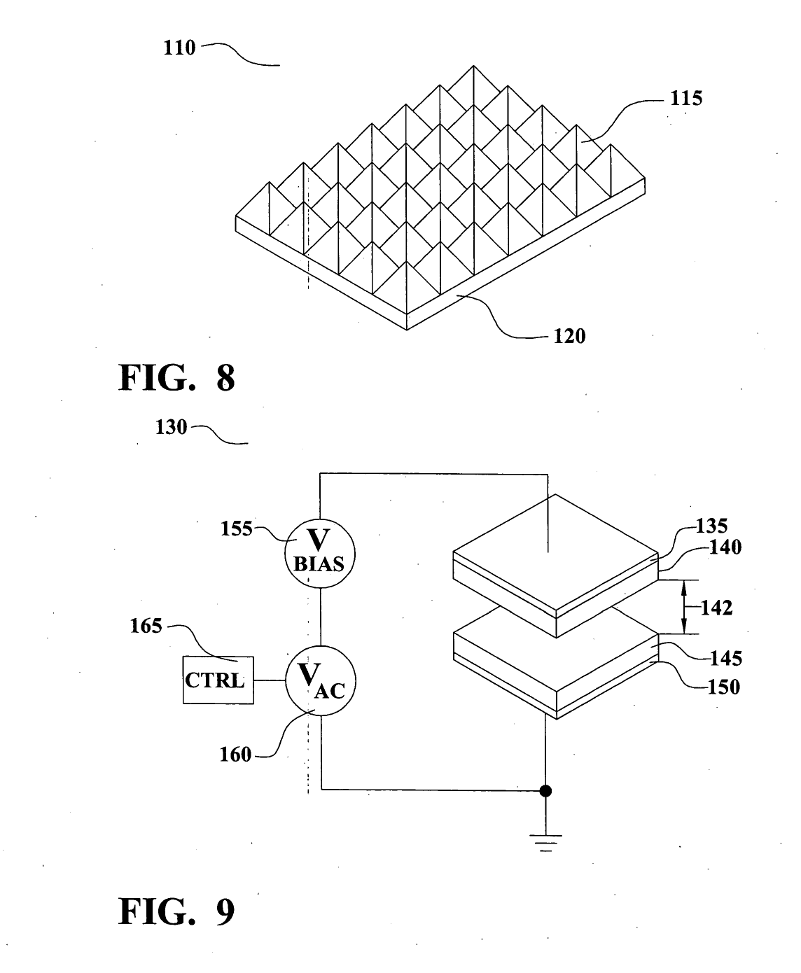

Referring now to FIG. 8, a third preferred embodiment of the present invention is illustrated. A sound diffusing or sound absorbing structure 110 comprising the conductive loaded resin-based material of the present invention is shown. The sound absorbing material 110 is formed from the conductive loaded resin-based material 120. The sound absorbing material 110 has shapes 115 such as tetrahedrons shown to provide deflection and channeling of acoustical waves to the mass of the material 120 to diffuse or dissipate unwanted sound. The tetrahedral shapes 115 are exemplary and may be any other pattern necessary to provide appropriate acoustical absorption or diffusion properties. In one embodiment, the sound absorbing structures 110 are easily formed by extrusion.

Referring now to FIG. 9, a fourth preferred embodiment of the present invention is illustrated. A capacitive ultrasound transducer 130 comprising the conductive loaded resin-based material of the present invention is shown. Capacitive ultrasound transducers have been demonstrated in the art to work efficiently for both air and immersion applications. A capacitive ultrasound transducer consists of a metallized membrane supported above a bottom electrode. The metallization on the membrane forms the top electrode. When an alternating current (AC) voltage is added to a direct current (DC) bias voltage that applied between the electrodes, a sinusoidal membrane vibration is obtained. If the biased membrane is exposed to an incoming acoustic field, electrical current is delivered to an external load. Basically, the capacitive ultrasound transducer converts electrical energy into mechanical energy and vice versa.

In the preferred embodiment, a capacitive ultrasound transducer 130 is formed comprising the conductive loaded resin-based material of the present invention. The capacitive ultrasound transducer 130 comprises a first conductive electrode 135 adhered to a membrane layer 140. The membrane layer is separated by a vacuum gap 142 from an insulation layer 145. A second conductive electrode 150 is adhered to the insulation layer 145. The first and second conductive electrodes 135 and 150 are formed from the conductive loaded resin-based materials of this invention. The conductive loaded resin-based materials are formulated to be sufficiently conductive to transfer the electrical energy of the transducer with low losses. The membrane 140 and the insulation layer 145 may also comprise conductive loaded resin-based material. The membrane 140 and the insulating layer 145 are formulated to have the appropriate properties for vibration for transmission of the acoustic waves or generation the electrical energy when exposed to the incoming acoustic field.

The first electrode 135 is connected to a DC biasing voltage source 155 which is connected to the AC voltage signal source 160. A control circuit 165 applies the necessary stimulus to control the AC voltage signal source 160 which generates the electrical energy which stimulates the membrane 145 vibration. The second electrode 150 and the AC voltage signal source 160 are connected to a common ground reference potential. A load resistance (not shown) would be switched into the circuit in place of the AC voltage signal source 160 for reception of acoustic waves and conversion to the electrical energy that is received across the load resistance. In one embodiment, the electrodes 135 and 150 are formed by injection molding. In another embodiment, the electrodes 135 and 150 are formed by extrusion.

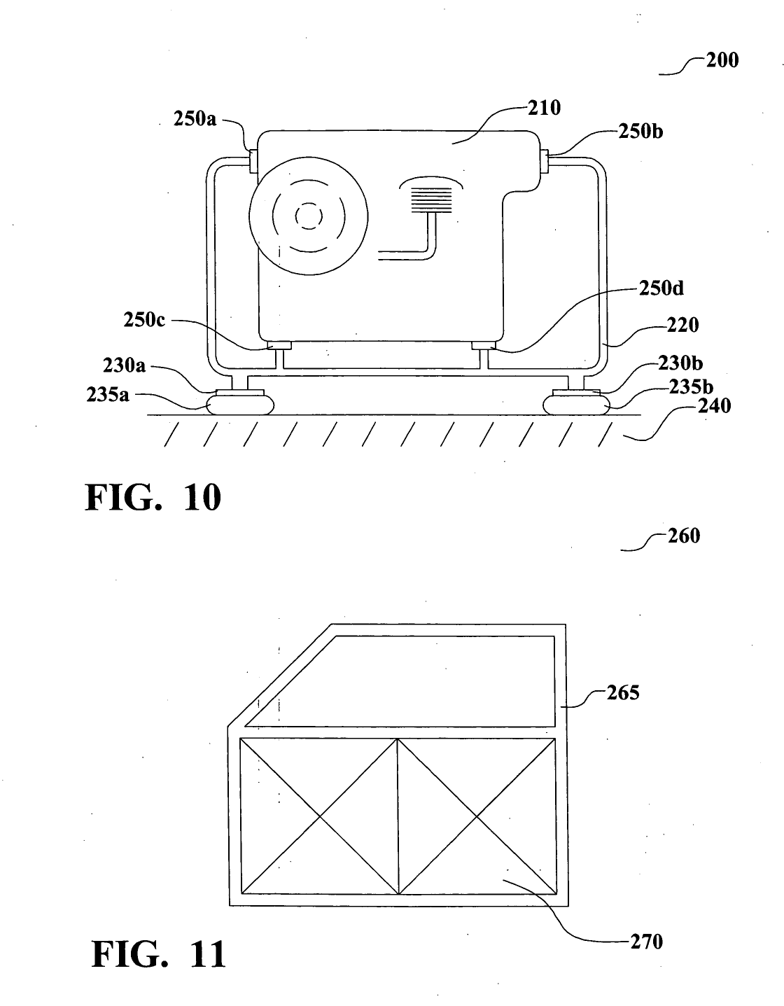

Referring now to FIG. 10 a fifth preferred embodiment 200 of the present invention is illustrated. Vibration or sound absorbing spacers, in this case vibration pads 235a and 235b and isolation bushings 250a, 250b, 250c, and 250d, comprising the conductive loaded resin-based material of the present invention are shown. In the exemplary embodiment, a motorized machine 210 is fixably attached to a metal frame 220. The metal frame 220 supports the motorized machine 210 above a floor 240. Isolation bushings 250a-250d are used at points where the frame 220 is attached to the machine 210. The isolation bushings 250a-250d comprise the conductive loaded resin-based material of the present invention. In one embodiment, the base resin material comprises an elastomeric material. When combined with the conductive loading material, as described herein, the isolation bushings 250a-250d absorb and dissipate vibrational energy from the machine 210 such that much of this energy does not pass into the frame 220. In one embodiment, pins or bolts are inserted through the isolation bushings 250a-250d to attach the machine 210 to the frame 220.

Vibration pads 235a and 235b are attached to the base, or feet 230a and 230b, of the frame 220. The vibration pads 235a and 235b comprise the conductive loaded resin-based material of the present invention. In one embodiment, the base resin material comprises an elastomeric material. When combined with the conductive loading material, as described herein, the vibration pads 235a and 235b absorb and dissipate vibration energy that is transmitted from the machine 210 and through the frame 220 such that much of this energy does not pass into the floor 240. In one embodiment, pins or bolts are inserted through the vibration pads 235a and 235b are attached the feet 230a and 230b of the frame 220. The vibration pads 235a and 235b are quite useful for the isolation of equipment and for the elimination of inter-equipment vibrational problems.

Vibration or sound absorbing spacers, such as are described in this exemplary embodiment of the present invention, are needed to dissipate the energy within the machine. The vibration pads and/or isolation bushings dissipate mechanical vibration by converting the mechanical energy into heat through molecular interaction (heat generated through friction). Additional embodiments of the conductive loaded resin-based material of the present invention for vibration damping and/or isolation include damping clips for brackets, including floor and ceiling systems, isolation of cooling fans or motors, isolation of equipment housings, isolation of electronic components, isolation of metal panels in motor vehicles, ships, and the like, isolation for compressor, heavy machinery, HVAC equipment, and the like.

FIG. 11 illustrates a sixth preferred embodiment 260 of the present invention showing sound or vibration absorbing panels 270 comprising the conductive loaded resin-based material of the present invention. In the embodiment, a sound or vibration absorbing panel 270 is attached to a door assembly 265 for a motor vehicle. The panel 270 comprises the conductive loaded resin-based material of the present invention. The panel 270 absorbs and dissipates vibrational energy such that road noise does not penetrate from the outside and through the door into the cab of the vehicle. In one embodiment, pins or bolts are inserted through the panel 270 to attach the panel 270 to the frame door 265.

In another embodiment, the panel 270 comprises a constrained layer damping system. Wherein a layer viscoelastic conductive loaded resin-based material is laminated to a rigid outer panel. The resulting composite panel 270 allows the thin viscoelastic layer to be put into shear deformation. As a result, vibration or sound energy is converted to heat through molecular friction in the conductive loaded resin-based material.

Additional embodiments of sound or vibration panels include ceiling, wall, and floor panels, and pipe and ductwork panels and wraps. Other embodiments include instrument panels, floor systems, firewall systems, chassis isolation, entertainment systems, and the like, for various types of motor vehicles.

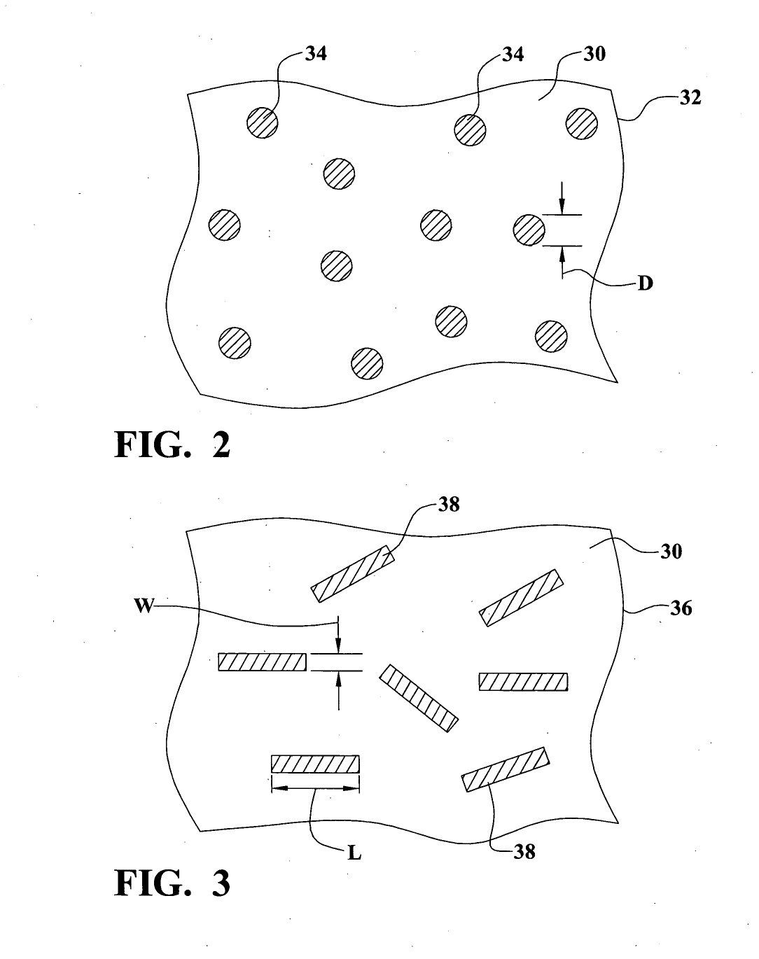

The conductive loaded resin-based material of the present invention typically comprises a micron powder(s) of conductor particles and/or in combination of micron fiber(s) substantially homogenized within a base resin host. FIG. 2 shows cross section view of an example of conductor loaded resin-based material 32 having powder of conductor particles 34 in a base resin host 30. In this example the diameter D of the conductor particles 34 in the powder is between about 3 and 12 microns.

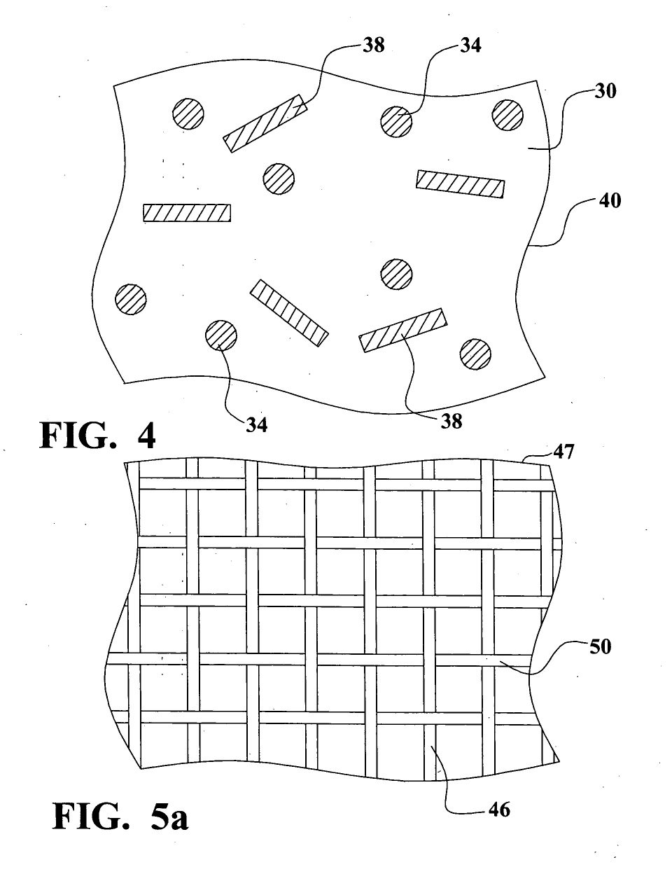

FIG. 3 shows a cross section view of an example of conductor loaded resin-based material 36 having conductor fibers 38 in a base resin host 30. The conductor fibers 38 have a diameter of between about 3 and 12 microns, typically in the range of 10 microns or between about 8 and 12 microns, and a length of between about 2 and 14 millimeters. The conductors used for these conductor particles 34 or conductor fibers 38 can be stainless steel, nickel, copper, silver, aluminum, or other suitable metals or conductive fibers, or combinations thereof. Superconductor metals, such as titanium, nickel, niobium, and zirconium, and alloys of titanium, nickel, niobium, and zirconium may also be used as micron conductive fibers in the present invention. These conductor particles and or fibers are substantially homogenized within a base resin. As previously mentioned, the conductive loaded resin-based materials have a sheet resistance between about 5 and 25 ohms per square, though other values can be achieved by varying the doping parameters and/or resin selection. To realize this sheet resistance the weight of the conductor material comprises between about 20% and about 50% of the total weight of the conductive loaded resin-based material. More preferably, the weight of the conductive material comprises between about 20% and about 40% of the total weight of the conductive loaded resin-based material. More preferably yet, the weight of the conductive material comprises between about 25% and about 35% of the total weight of the conductive loaded resin-based material. Still more preferably yet, the weight of the conductive material comprises about 30% of the total weight of the conductive loaded resin-based material. Stainless Steel Fiber of 6-12 micron in diameter and lengths of 4-6 mm and comprising, by weight, about 30% of the total weight of the conductive loaded resin-based material will produce a very highly conductive parameter, efficient within any EMF spectrum. Referring now to FIG. 4, another preferred embodiment of the present invention is illustrated where the conductive materials comprise a combination of both conductive powders 34 and micron conductive fibers 38 substantially homogenized together within the resin base 30 during a molding process.

Referring now to FIGS. 5a and 5b, a preferred composition of the conductive loaded, resin-based material is illustrated. The conductive loaded resin-based material can be formed into fibers or textiles that are then woven or webbed into a conductive fabric. The conductive loaded resin-based material is formed in strands that can be woven as shown. FIG. 5a shows a conductive fabric 42 where the fibers are woven together in a two-dimensional weave 46 and 50 of fibers or textiles. FIG. 5b shows a conductive fabric 42′ where the fibers are formed in a webbed arrangement. In the webbed arrangement, one or more continuous strands of the conductive fiber are nested in a random fashion. The resulting conductive fabrics or textiles 42, see FIG. 5a, and 42′, see FIG. 5b, can be made very thin, thick, rigid, flexible or in solid form(s).

Similarly, a conductive, but cloth-like, material can be formed using woven or webbed micron stainless steel fibers, or other micron conductive fibers. These woven or webbed conductive cloths could also be sandwich laminated to one or more layers of materials such as Polyester(s), Teflon(s), Kevlar(s) or any other desired resin-based material(s). This conductive fabric may then be cut into desired shapes and sizes.

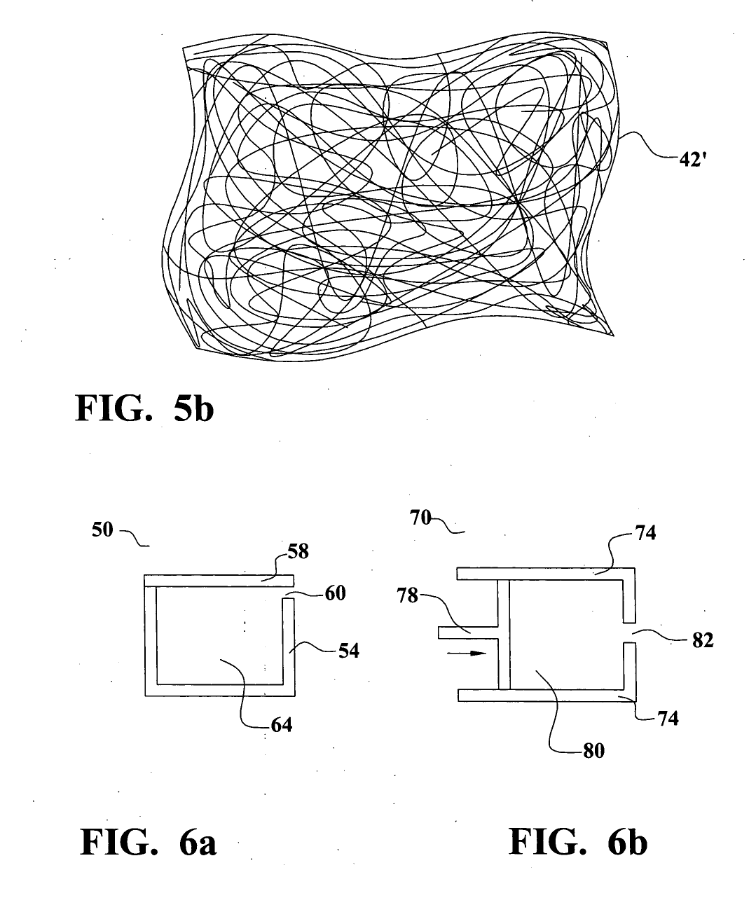

Acoustical devices formed from conductive loaded resin-based materials can be formed or molded in a number of different ways including injection molding, extrusion or chemically induced molding or forming. FIG. 6a shows a simplified schematic diagram of an injection mold showing a lower portion 54 and upper portion 58 of the mold 50. Conductive loaded blended resin-based material is injected into the mold cavity 64 through an injection opening 60 and then the substantially homogenized conductive material cures by thermal reaction. The upper portion 58 and lower portion 54 of the mold are then separated or parted and the acoustical device is removed.

FIG. 6b shows a simplified schematic diagram of an extruder 70 for forming acoustical devices using extrusion. Conductive loaded resin-based material(s) is placed in the hopper 80 of the extrusion unit 74. A piston, screw, press or other means 78 is then used to force the thermally molten or a chemically induced curing conductive loaded resin-based material through an extrusion opening 82 which shapes the thermally molten curing or chemically induced cured conductive loaded resin-based material to the desired shape. The conductive loaded resin-based material is then fully cured by chemical reaction or thermal reaction to a hardened or pliable state and is ready for use. Thermoplastic or thermosetting resin-based materials and associated processes may be used in molding the conductive loaded resin-based articles of the present invention.

The advantages of the present invention may now be summarized. An effective acoustical device is achieved. A method to form an acoustical device is also achieved. The acoustical device is molded of conductive loaded resin-based material. The acoustical device is molded of conductive loaded resin-based material where the device characteristics can be altered or the visual characteristics can be altered by forming a metal layer over the conductive loaded resin-based material. A speaker enclosure device is molded of the conductive loaded resin-based material. An acoustical absorbing or diffusing device is molded of the conductive loaded resin-based material. A capacitive ultrasound transducer is molded of conductive loaded resin-based material. An acoustical material with excellent sound reflection properties is achieved.

As shown in the preferred embodiments, the novel methods and devices of the present invention provide an effective and manufacturable alternative to the prior art.

While the invention has been particularly shown and described with reference to the preferred embodiments thereof, it will be understood by those skilled in the art that various changes in form and details may be made without departing from the spirit and scope of the invention.

1. A method to form a speaker device, said method comprising:
providing a transducer capable of translating electrical energy into sound energy;
providing a conductive loaded, resin-based material comprising conductive materials in a resin-based host; and
forming said conductive loaded, resin-based material into an enclosure surrounding said transducer.

2. The method according to claim 1 wherein the percent by weight of said conductive materials is between about 20% and about 50% of the total weight of said conductive loaded resin-based material.

3. The method according to claim 1 wherein said conductive materials comprise micron conductive fiber.

4. The method according to claim 2 wherein said conductive materials further comprise conductive powder.

5. The method according to claim 1 wherein said conductive materials are metal.

6. The method according to claim 1 wherein said enclosure is designed to fit over a human ear.

7. The method according to claim 1 wherein said speaker device further comprises:
providing a second said transducer; and
forming said conductive loaded, resin-based material into a second enclosure surrounding said second transducer.

8. The method according to claim 1 wherein said conductive loaded resin-based material further comprises ferromagnetic loading such that said enclosure is magnetic.

9. The method according to claim 1 further comprising forming a metal layer overlying said enclosure.

10. The method according to claim 1 wherein said conductive materials are nickel plated carbon micron fiber, stainless steel micron fiber, copper micron fiber, silver micron fiber or combinations thereof.

11. A method to form an acoustical device, said method comprising:
providing a conductive loaded, resin-based material comprising conductive materials in a resin-based host wherein the weight of said conductive materials is between 20% and 50% of the total weight of said conductive loaded resin-based material; and
forming said conductive loaded, resin-based material into an array of three-dimensional shapes.

12. The method according to claim 11 wherein said conductive materials are nickel plated carbon micron fiber, stainless steel micron fiber, copper micron fiber, silver micron fiber or combinations thereof.

13. The method according to claim 11 wherein said conductive materials comprise micron conductive fiber and conductive powder.

14. The method according to claim 13 wherein said conductive powder is nickel, copper, or silver.

15. The method according to claim 13 wherein said conductive powder is a non-conductive material with a metal plating of nickel, copper, silver, or alloys thereof.

16. The method according to claim 11 wherein said step of forming said structural layer comprises:
loading said conductive loaded, resin-based material into a chamber;
extruding said conductive loaded, resin-based material out of said chamber through a shaping outlet; and
curing said conductive loaded, resin-based material to form said three-dimensional shapes.

17. The method according to claim 11 wherein said step of molding comprises:
injecting said conductive loaded, resin-based material into a mold;
curing said conductive loaded, resin-based material; and
removing said three-dimensional shape from said mold.

18. The method according to claim 11 wherein said three-dimensional shapes comprise tetrahedral shapes.

19. A method to form a capacitive acoustical transducer device, said method comprising:
providing a conductive loaded, resin-based material comprising micron conductive fiber in a resin-based host;
forming said conductive loaded, resin-based material into a first conductive electrode;
forming said conductive loaded, resin-based material into a second conductive electrode;
fixing said first conductive electrode to a membrane layer; and
fixing said second conductive electrode to an insulating layer.

20. The method according to claim 19 wherein said micron conductive fiber is stainless steel.

21. The method according to claim 19 further comprising conductive powder.

22. The method according to claim 19 wherein said micron conductive fiber has a diameter of between about 3 μm and about 12 μm and a length of between about 2 mm and about 14 mm.

23. The method according to claim 19 wherein said backing layer comprises a fabric or mesh of said conductive loaded resin-based material.

24. The method according to claim 19 wherein said conductive loaded resin-based material further comprises ferromagnetic loading such that said structural layer is magnetic.

25. The method according to claim 20 further comprising a metal layer overlying said structural layer.
